(19) United States
(12) Patent Application Publication
(10) Pub. No.: US 2024/0329155 A1
(43) Pub. Date: Oct. 3, 2024

(54) Charging cable, charging station, charging system, and method for transmitting a charging current from a charging station to a traction battery

(71) Applicant: Webasto SE, Stockdorf (DE)

(72) Inventor: Michael Finsinger, Stockdorf (DE)

(21) Appl. No.: 18/575,934

(22) PCT Filed: Jul. 1, 2022
(86) PCT No.: PCT/EP2022/068228

§ 371 Date: Jan. 2, 2024

(30) Foreign Application Priority Data
Jul. 2, 2021 (DE) 102021117089.3

(51) Int. Cl. G01R 31/58; B60L 53/18; B60L 53/30; G01K 1/02; G01K 3/06; H02J 7/00

(52) U.S. Cl. CPC G01R 31/58; B60L 53/18; B60L 53/305; G01K 1/026; G01K 3/06; H02J 7/0047

(57) ABSTRACT

The invention relates to a charging cable, a charging station, a charging system, and a method for transmitting a charging current from a charging station to a traction battery in order to charge or discharge the traction battery, for example in order to charge or discharge a traction battery of an electric vehicle, by means of a charging cable which is connected to the charging station and the traction battery, where losses occurring in the charging cable while transmitting energy to the traction battery are calculated using cable-specific data including temperature values of each of the charging current lines of the charging cable, said temperature values being ascertained and transmitted in the charging cable.

### CROSS-REFERENCE TO RELATED APPLICATIONS

This application is a 35 U.S.C. § 371 National Stage Entry of International Application No. PCT/EP2022/068228 filed Jul. 1, 2022, which claims the priority benefit of German Patent Application Serial Number DE 10 2021 117 089.3 filed Jul. 2, 2021, all of which are incorporated herein by reference in their entirety for all purposes.

### TECHNICAL FIELD

The present invention relates to a charging cable, a charging station and a charging system and a method for transmitting a charging current from a charging station to a traction battery for charging or discharging the traction battery, for example for charging or discharging a traction battery of an electric vehicle.

### BACKGROUND

The proportion of pure electric vehicles and electric hybrid vehicles, hereinafter referred to as “electric vehicles” for the sake of simplicity, is growing continuously. Accordingly, there is a growing need to provide suitable charging systems for the transmission of electrical energy from a charging station to a rechargeable traction battery of such an electric vehicle. New charging stations and charging cables are therefore the subject of current research and development.

For energy transmission for charging, the electric vehicle, or more precisely the traction battery, must be connected to the charging station. As a rule, this is done by using an appropriately designed charging cable.

With regard to the amount of energy used to charge the traction battery and how it is determined, a distinction must be made between private charging stations and commercial charging stations. Private charging stations are usually assigned to a specific user. For example, a private charging station may be installed in a private garage of an electric vehicle user. The energy used to charge the residential user's traction battery with his private charging station can be determined simply by connecting an appropriate meter between the mains and the charging station or, alternatively, by using the meter already available for the user's household.

The situation is different in the case of commercial charging stations, where an operator of the charging station provides users of electric vehicles with the charging of their electric vehicles at the operator's charging station for a fee. In such commercial charging methods, the user of the electric vehicle, i.e., the operators customer, wants to pay only for the amount of energy that has actually been used to charge his vehicle, in particular his traction battery, without calculating energy losses that arise, for example, within the charging station or in the charging cable. In the case of low charging currents, it may be possible to neglect the losses incurred in the charging cable. However, in the case of larger currents or tight tolerances for the determination, the resulting measurement error due to the losses in the charging cable must be taken into account for the energy calculation.

For this purpose, the energy tapped by the customer for charging can be measured at the point of withdrawal. This usually happens in the connector of the charging cable vehicle at the vehicle side, i.e., the charging connector at the end of the cable of the charging station if the cable is firmly connected to the charging station. In order to be able to determine the energy emitted precisely, the current and voltage at the transmission point must be determined accordingly. The voltage must be determined at the connector of the vehicle or at the vehicle side of the charging cable. This can be done, for example, by means of a so-called four-wire measurement or four-conductor measurement. In this measurement, the voltages at the connector or the cable end at the vehicle are recorded, wherein the number of voltages to be recorded depends on the type of cable and the associated power transmission, such as whether the energy is transmitted via direct current or alternating current and with how many phases. Alternatively, the voltage can be recorded at the cable terminals of the charging station, i.e., the end of the charging cable on the charging station side, wherein the losses in the charging cable must then be subtracted from the energy that can be determined at the charging station by means of the voltage on the cable terminals and the measured current in order to determine the energy tapped by the electric vehicle. The losses in the cable or the cable losses can be calculated if the relevant cable parameters are known.

However, in order to determine the voltage at the vehicle connector of the charging cable, a separate sensing line unit is required in the charging cable, which is usually composed of a pair of wires. When charging by direct current, one sensing line unit is sufficient for this. If, on the other hand, alternating current is used for charging, at least a separate sensing line unit must be provided for each phase. With three phases, this corresponds to three sensing line units. In the charging cable, six additional cores or wires would therefore have to be provided for the measurement alone. As a rule, such sensing lines are not provided for in currently available commercial charging cables. Accordingly, there is also a lack of such connections in the connectors of the charging cable. In addition, the complexity of the structure of the charging cable increases with increasing numbers of phases, which is noticeable, among other things, in the installation (more conductors have to be connected) and the cable costs (more conductors in the cable).

Another way to determine the losses in the charging cable is to calculate or estimate the losses using the cable parameters required for this, in particular the cable resistance, which in turn results from the length of the conductor, the specific electrical resistance of the conductor and the cross-sectional area of the conductors. However, the cable parameters must then be known. Furthermore, a clearly defined cable must be clearly and permanently assigned to the respective charging station, as the cable parameters inherent in the charging cable are also different every time the charging cable is changed.

Accordingly, it is necessary that the charging station, or its energy meter, must store the cable parameters in order to calculate the cable losses. Accordingly, the charging station, or its energy meter, cannot be used with any other cable, as this would affect the billing-relevant data.

When entering the cable parameters into the charging station during production, it must be ensured that the defined cable is actually used at the installation location of the charging station. This is often accompanied by regulatory requirements, in particular regulatory requirements relating to calibration law. In addition, the mandatory adherence to the pairing of the charging cable and charging station leads to sales and logistical challenges, for example if the operator of the charging station and/or the customer wants a different cable length or if a shipment with the cable defined for the charging station has an excessively large parcel weight. Furthermore, such a clear assignment of the charging cable and charging station leads to a larger stock to be held by the manufacturer.

If, on the other hand, the cable parameters are entered during installation at the installation site, this must comply with the often existing regulatory requirements of calibration law. For example, it may be required by the authorities that the installer is specially trained and/or officially certified. Furthermore, it must be ensured that the settings of the cable parameters cannot be set or changed incorrectly or even fraudulently.

In order to take account of at least some of the hurdles described above, it is known to develop a charging cable in the form of an “intelligent charging cable”, which accordingly includes a computing device for determining or calculating the amount of energy transmitted to the electric vehicle and a communication device for transmitting the determined amount of energy to a central control unit.

Such charging cables are known, for example, from US 2020/231063 A1 or DE 10 2018 201 698 A1. Such charging cables have a complex structure and are correspondingly complex to manufacture and expensive. Not only must these intelligent charging cables include the computing device, but also the communication device with additional separate communication channels, such as additional conductors, which are necessary for communication.

The cable parameters, in particular the ohmic resistances of the charging current lines in the cable used for transmitting the charging current or energy from the charging station to the traction battery, are also temperature dependent. For example, in order to calculate the conductor losses as accurately as possible, the temperature of the cable must be determined as precisely as possible, because the cable parameters are usually specified for a certain temperature, for example for 20° C.

In order to minimize temperature-dependent inaccuracies or deviations in the calculation of conductor losses, it is known from DE 10 2017 221 298 A1 to measure the ohmic resistance of a conductor shield of an energy transmission conductor. Assuming that the temperature change of the conductor shield is equal to the temperature change of the charging current cable, the determined power losses are converted with a predetermined, fixed ratio to the change in the resistance of the conductor shield.

### SUMMARY

Based on the known prior art, it is an object of the present invention to provide an improved charging cable, an improved charging station, an improved charging system and an improved method for transmitting a charging current from a charging station to a traction battery.

The object is achieved by a charging cable for transmitting a charging current from a charging station to a traction battery for charging or discharging the traction battery, preferably for charging or discharging a traction battery of an electric vehicle, having the features of claim 1. Advantageous developments result from the dependent claims, the description and the figures.

Accordingly, a charging cable for transmitting a charging current from a charging station to a traction battery for charging or discharging the traction battery, preferably for charging or discharging a traction battery of an electric vehicle, is proposed, containing a plurality of charging current lines designed and configured to transmit the charging current from the charging station to the traction battery.

Further, in the charging cable, a temperature sensor unit is assigned to each charging current line, which determines the temperature of the assigned charging current line, wherein the temperature sensor units are connected to a signal line for providing the temperature values determined by the temperature sensor units to the charging station.

The term “charging current lines” here refers to the conductors that are designed and configured to transmit the charging current for charging or discharging the traction battery from the charging station to the traction battery. In an alternating current version, the charging current lines comprise the phase conductors or synonymously outer conductors, for example the phase conductors L1, L2, L3 in the case of a three-phase alternating current version. In a direct current version, the charging current lines include the “DC+” and “DC−” conductors.

The invention has the advantage that the temperature of all charging current lines can be determined directly in the charging cable. Accordingly, it is possible to compensate for the influence of temperature on the power losses in the charging cable particularly precisely. In other words, the calculation of the power losses based on the measurement of the temperature of all charging current lines, including the temperatures of all charging current lines, can be approximated particularly closely to the actual power losses. As a result, the systematic error caused by a change in the temperature of the conductor can be calculated particularly precisely for determining the energy measurement transmitted to the connector of the cable at the vehicle side.

By minimizing the systematic error due to the temperature change of the charging cable, regulatory requirements, for example with regard to calibration law or other measurement requirements, such as billing accuracy tolerances, can be better met.

The preferably digital communication to the temperature sensor units takes place centrally via the common signal line. Thus, the number of possible sensors in the charging cable, including the wiring harness and any connectors, is not limited by a possible maximum number of signal lines in the charging cable, as is disadvantageous in the prior art.

In addition to the preferred digital temperature sensor units, other sensors or memories can be connected to the signal line. In the case of multi-phase charging systems, especially three-phase alternating current charging systems, signal lines that would otherwise be required for temperature measurement at the charging current line contacts, in other words the power contacts, can be saved. As a result, the number of signal cables can be minimized, thus saving costs, the cable thickness is reduced and accordingly a smaller possible permissible bending radius of the charging cable can be realized.

According to a preferred embodiment, exactly one signal line is provided in the charging cable. The signal line is preferably configured and designed for transmitting digital signals.

The signal line preferably includes a data wire (DATA), through which preferably digital data are transmitted, and a ground wire (GND). The signal line is preferably designed in such a way that the power supply to connected units is carried out via the data wire. According to a preferred embodiment, the signal line corresponds to a two-conductor 1-wire BUS with a parasitic power supply.

Alternatively, instead of providing a ground wire, the protective earth conductor (PE) or the neutral conductor (N) of the primary energy transmission of the charging cable can also be used as a ground wire, or respectively, the ground wire can also be formed by the protective earth conductor (PE) or the neutral conductor (N) of the primary energy transmission.

Preferably, the temperature sensor units are digital temperature sensor units. In other words, the temperature sensor unit provides the measured temperature value as a digital signal or in the form of digital data.

According to a preferred embodiment, each temperature sensor unit is configured and designed so that the digital signals thereof contain an identifier that preferably uniquely identifies the temperature sensor unit and the temperature value of the charging current line assigned to the temperature sensor unit and/or an average temperature value of the charging lines at a predetermined location on the charging cable. For example, the temperature value can preferably be clearly assigned to a specific temperature sensor unit, a specific location of the charging cable and/or a specific charging current line, for example the phase conductor L1, L2, or L3 in the case of the three-phase alternating current version of the charging cable, or the DC− or DC− conductor in the case of the direct current version of the charging cable. The identifier can assign the transmitted temperature value as belonging to the charging current lines. If the identifier is a unique identifier, the temperature value can—if necessary—even be clearly assigned to a specific one of the charging current lines or to a specific location on the charging cable.

According to a preferred embodiment, the signal line is a data bus conductor, preferably a standard bus, a proprietary bus, or a 1-wire bus.

According to another preferred embodiment, the temperature sensor units are assigned to the charging current lines in such a way that one, preferably each, temperature sensor unit is assigned to exactly one charging current line at a time, wherein the respective temperature sensor unit only determines the temperature of the charging current line assigned to it.

Alternatively or additionally, the temperature sensor units are assigned to the charging current lines in such a way that temperature sensor units are arranged spaced apart from each other at different points of the charging cable and each of the spaced apart temperature sensor units determines an average temperature of the charging current lines at the respective point.

For determining the average temperature of the charging current lines, preferably of all charging current lines at the respective point, the corresponding temperature sensor unit is preferably arranged at essentially the same distance from the charging current lines, preferably in the middle between the charging current lines. Due to the thermal coupling of the charging current lines in the wiring harness or in the charging cable, the average temperature, in other words an average value of the temperatures of the individual charging current lines, can be determined at the respective point.

According to a preferred embodiment, a memory module designed and configured for the storage of cable-specific data, preferably an EEPROM, is provided in the charging cable, which is preferably communicatively connected to the signal line, wherein the cable-specific data preferably include at least one from a length of the charging cable and/or a length of the wiring harness, a cable resistance, preferably in relation to a reference temperature T_{REF}, a specific cable resistance per given unit of length, preferably in relation to a reference temperature T_{REF}, a specific conductor resistance of at least one of the charging current lines, preferably in relation to a reference temperature T_{REF}, a cross-sectional area of at least one of the charging current lines, and/or information about the type of cable, wherein the information includes at least one from information about the type of charging voltage, preferably alternating current or direct current, over a plurality of the phases of the cable, a manufacturing site, a serial number, and a manufacturer. Thus it can be ensured that the correct data are used to calculate the conductor losses in the cable while charging the traction battery through the cable.

According to a preferred embodiment, a computing unit is arranged in the charging cable, preferably at least partially in a connector of the charging cable at the vehicle side, wherein the computing unit is preferably connected to the signal line.

According to a preferred embodiment, the computing unit is connected to at least one temperature sensor unit and/or forms a temperature sensor unit together with a temperature sensor, preferably an analog temperature sensor.

To discharge the battery, energy is transmitted from the battery to the charging station, in other words, energy is taken from the battery towards the charging station in a per se known way.

The above object is further achieved by a charging station for the transmission of a charging current to a traction battery for charging or discharging the traction battery, preferably for charging or discharging a traction battery of an electric vehicle, with the features of claim 8. Advantageous developments result from the dependent claims as well as the present description and the figures.

Accordingly, a charging station for the transmission of a charging current to a traction battery for charging or discharging the traction battery, preferably for charging or discharging a traction battery of an electric vehicle, is proposed, containing at least one charging cable connection for connecting a charging cable, the charging cable connection having at least one conductor contact for contacting a charging current line of the charging cable configured for charging current transmission, and at least one signal contact for contacting a signal line of the charging cable configured and designed for signal transmission, and further containing a computing device connected to the at least one signal contact for calculating losses occurring in the charging cable connected to the charging cable connection during the transmission of charging current to the traction battery based on cable-specific data.

The charging station is also provided in such a way that the computing device is designed and configured to calculate the losses in the charging cable by taking into account temperature values of the charging current lines of the charging cable provided via the signal line of the charging cable for temperature compensation.

The charging station can achieve the advantages and effects described with regard to the charging cable in an analogous way. Accordingly, the description given above with regard to the charging cable also pertains to the charging station.

According to a preferred embodiment, the computing device is configured and designed to receive the temperature values from the signal line in the form of digital signals, wherein the digital signals preferably include at least one identifier uniquely identifying a temperature sensor unit of the charging cable and a temperature value of a charging current line associated with the temperature sensor unit.

The above object is further achieved by a charging system for transmitting electrical energy from a charging station to a traction battery for charging or discharging the traction battery, preferably for charging or discharging the traction battery of an electric vehicle, by means of a charging cable connected to the charging station and the traction battery with the features of claim 10. Advantageous developments result from the present description and the figures.

Accordingly, a charging system is proposed for transmitting a charging current from a charging station to a traction battery for charging or discharging the traction battery, preferably for charging or discharging the traction battery of an electric vehicle, by means of a charging cable connected to the charging station and the traction battery. The charging system contains a charging cable in accordance with one of the above embodiments and/or a charging station in accordance with one of the above embodiments.

The fact that the charging system includes a charging cable in accordance with one of the above embodiments and/or a charging station in accordance with one of the above embodiments means that the advantages and effects asserted in this regard can also be achieved by the charging system.

The above object is further achieved by a method for transmitting a charging current from a charging station to a traction battery for charging or discharging the traction battery, preferably for charging or discharging the traction battery of an electric vehicle, by means of a charging cable connected to the charging station and the traction battery with the features of claim 11. Advantageous developments of the method result from the dependent claims as well as the present description and figures.

Accordingly, a method is proposed for transmitting a charging current from a charging station to a traction battery for charging or discharging the traction battery, preferably for charging or discharging the traction battery of an electric vehicle, including the following steps:

Providing electrical energy via the charging station. Conducting the electrical energy from the charging station to the traction battery via a charging cable connected to the charging station and the traction battery. Calculating losses occurring in the charging cable during energy transmission to the traction battery using cable-specific data.

The method also includes the determination of the temperature of each charging current line of the charging cable configured and designed for the transmission of the charging current from the charging station to the traction battery by means of temperature sensor units each assigned to a respective charging current line, the transmission of the determined temperature values to the charging station via a signal line of the charging cable connected to the temperature sensor units, and the calculation of the losses occurring in the charging cable during the energy transmission to the traction battery, taking into account the temperature values determined and transmitted in the charging cable of each of the charging current lines for temperature compensation.

The method allows the advantages and effects described with regard to the charging cable and the charging station to be achieved in an analogous way.

During discharging of the charging cable, the “provision of the electrical energy” is understood to mean the provision of an energy withdrawal. Accordingly, the charging current is a negative charging current when viewed in the direction towards the traction battery.

### BRIEF DESCRIPTION OF THE FIGURES

Preferred other embodiments of the invention are explained in more detail in the following description of the figures. In the figures:

FIG. 1 shows schematically a side view of a charging system for charging or discharging a traction battery of an electric vehicle;

FIG. 2 shows schematically a side view of a charging cable of the charging system from FIG. 1;

FIG. 3 shows schematically a cross-sectional view of a charging system for charging or discharging a traction battery according to another embodiment;

FIG. 4 shows schematically a cross-sectional view of a charging system for charging or discharging a traction battery according to another embodiment;

FIG. 5 shows schematically a cross-sectional view of a charging system for charging or discharging a traction battery according to another embodiment;

FIG. 6 shows schematically a cross-sectional view through a charging system for charging or discharging a traction battery according to another embodiment;

FIG. 7 shows schematically a cross-sectional view of a charging system for charging or discharging a traction battery according to another embodiment; and

FIG. 8 shows schematically a cross-sectional view of a charging system for charging or discharging a traction battery according to another embodiment.

### DETAILED DESCRIPTION OF PREFERRED EMBODIMENTS

In the following, preferred exemplary embodiments are described on the basis of the figures. In this method, identical, similar or equivalent elements in the different figures are provided with identical reference signs, and a repeated description of these elements is sometimes dispensed with in order to avoid redundancies.

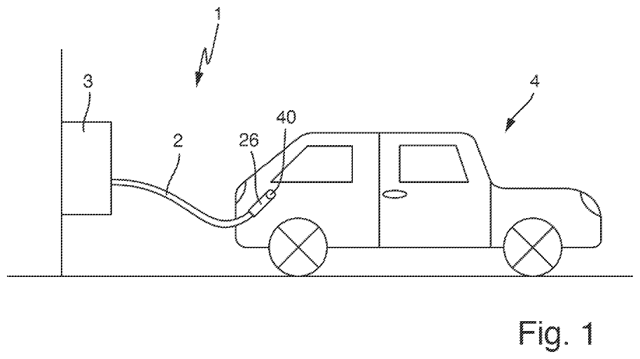

FIG. 1 shows schematically a side view of a charging system 1 for charging or discharging a traction battery (not shown) of an electric vehicle 4. In the present case, the charging system 1 contains an optional wall-mounted charging station 3, which is connected to the electric vehicle 4 via a charging cable 2 connected to or attached to the charging station 3 by connecting a vehicle side connector 26 of the charging cable 2 into a charging socket 40 of the electric vehicle 4 that corresponds to the connector 26. The connector 26 and the charging socket 40 may be substantially in the form of, but not limited to, a connector type according to IEC 62196 Type 2, Type 1 or Type 3, or according to the CHAdeMo system.

In the present case, the charging station 3 is configured for operation for commercial purposes, i.e., is in the form of a commercial charging station 3, with which an operator makes it available to users of the electric vehicles 4 to charge their electric vehicles 4 at the charging station 3 for a fee. Accordingly, the energy losses occurring in the charging cable 2 during the charging of the traction battery must be determined. In the present case, the charging station 3 is designed and configured to calculate the losses occurring in the charging cable during the energy transmission to the traction battery 2 based on cable-specific data, in this case by the product of the square of the current flowing through the charging cable 2 and the cable resistance of the charging cable 2. While the current delivered to the charging cable 2 and the voltage can be measured or determined in the charging station 3 for energy calculation, the power losses in the charging cable 2 are determined from the cable resistance determined from the cable-specific data based on the resistance of the charging current lines, i.e., the power conductors, and the measured current values. For this purpose, the data can directly contain the cable resistance, or can include parameters from which the cable resistance can be calculated, such as a specific conductor resistance, a conductor cross-section and a conductor length. The losses from the charging cable 2 can be deducted from the measured energy determined in the charging station 3 for the correct calculation of the electrical energy output at the charging connector 26 at the vehicle side.

For example, the cable-specific data may include a specific conductor resistance of the charging current lines, which is given as a reference value in relation to an assigned temperature T_{REF} of the charging current lines. As a non-limiting example, the conductor resistance can be calculated according to a preferred version using the following relation:

$$Rwire = L * \frac{φ}{A} \qquad ( 1 )$$

Here, “Rwire” corresponds to the conductor resistance, “φ” is the specific electrical resistance of the conductor in [Ohm*mm²/m], “L” is the length of the conductor, and “A” is the cross-sectional area of the conductor.

As described above, the conductor resistance of the charging current lines is temperature dependent. It can be calculated as a non-limiting example according to a preferred version using the following relation:

$$Rwire ( T ) = {Rwire}_{REF} * [ 1 + α * ( T - {T}_{REF} ) ] = L * \frac{{φ}_{REF}}{A} * [ 1 + α * ( T - {T}_{REF} ) ] \qquad ( 2 )$$

Here, “Rwire(T)” corresponds to the resistance value of the conductor at a certain temperature T, “Rwire_{REF}” corresponds to the resistance value at a given reference temperature T_{REF}, for example 20° C., and “φ_{REF}” corresponds to the specific resistance at the reference temperature T_{REF}, and “α” to the temperature coefficient of the conductor material (for example copper). The reference values Rwire_{REF} and/or φ_{REF} as well as the temperature coefficient α can be included in the cable parameters and/or transmitted to the charging station 3 or the computing device (not shown here) or entered manually via an optional interface.

Thanks to the aforementioned temperature compensation, it is possible to make the calculation of the charging energy and the conductor losses particularly accurate, so that even strict regulations of calibration law can be complied with.

Accordingly, it is necessary to know the temperatures T of the charging current lines in the cable 2. For this purpose, temperature sensor units are provided in the charging cable 2 for determining the temperatures T of the charging current lines, as described in detail with reference to the following figures. For this purpose, the temperature sensor units communicate with the computing device (not shown here) arranged in the charging station 3 for calculating losses occurring in the charging cable (2) connected to the charging cable connection (30) during the energy transmission to the traction battery based on cable-specific data and the temperature values of the charging current lines determined by the temperature sensor units, both when charging the traction battery and when discharging the traction battery.

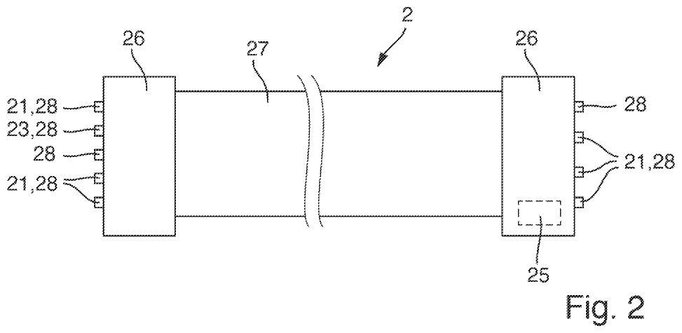

FIG. 2 shows schematically a side view of a charging cable 2 of the charging system from FIG. 1. The charging cable 2 is designed for transmitting electrical energy from a charging station 3 to a traction battery for charging or discharging the traction battery, preferably for charging or discharging a traction battery of an electric vehicle 4. The charging cable 2 contains a wiring harness 27, which contains a plurality of parallel conductors (not shown here). At each end of the wiring harness 27 there is a connector 26. The wires in the connectors 26 are connected to contacts 28 provided for this purpose in the connectors 26 according to their functionality, wherein the connectors 26 have different designs. Of the contacts 28, only a few are shown in FIG. 2 as examples. The connector 26 shown in FIG. 2 on the left corresponds to a connector 26 on the charging station, the connector 26 shown in FIG. 2 on the right corresponds to a connector 26 on the vehicle. Both connectors 26 each comprise a plurality of conductor contacts 21, which are connected to a corresponding number of conductors of the charging cable 2 for energy transmission. According to this version, the charging cable 2 is optionally in the form of a three-phase alternating current charging cable 2 for 400 V and accordingly comprises a conductor contact 21 per phase conductor, the so-called outer conductors (L1, L2, L3), a conductor contact 21 for the neutral conductor (N) and a conductor contact 21 for grounding or the protective contact (PE).

Alternatively, the end of the charging cable on the charging station side, instead of encompassing a connector 26 as shown, may be designed so that the conductors of the charging cable 2 can be connected directly to the charging station 3 at the charging station side, preferably with a screw connection or a clamp connection, and/or with a separable or non-separable plug-in connector.

Accordingly, it can be prevented that a customer can remove the charging cable 2 himself. This may be prevented, for example, due to regulatory requirements.

The charging cable 2 optionally contains a memory module 25, which is designed and configured to store cable-specific data and is integrated in the charging cable 2, in this case optionally integrated in the connector 26 at the vehicle side. Alternatively or additionally, the memory module 25 can also be integrated in the wiring harness 27, for example at the charging station side, preferably if the charging cable 2 does not include a connector on the charging station side, and/or in the connector 26 at the charging station side.

The cable-specific data may contain at least one of a length of the charging cable and/or a length of the wiring harness, a cable resistance, a specific cable resistance per given unit length, a specific conductor resistance of at least one of the lines, and a cross-sectional area of at least one of the lines. The aforementioned values are preferably reference values related to a given reference temperature, for example 20° C.

In addition, cable-specific data may include information about the type of cable, and the information may be at least one from the information about the type of charging voltage, preferably alternating current or direct current, about a number of phases of the cable, a manufacturing site, a serial number, and a manufacturer.

The memory module 25 can optionally be designed and configured to store the cable-specific data unencrypted or encrypted and/or signed and/or to make it available for retrieval in an unencrypted or encrypted and/or signed form.

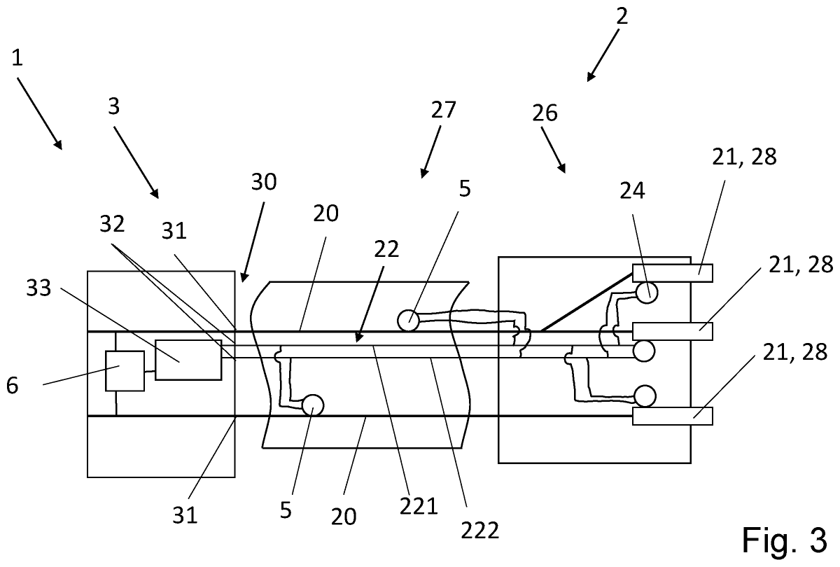

FIG. 3 shows schematically a cross-sectional view through a charging system 1 for charging or discharging a traction battery of an electric vehicle 4 according to another embodiment.

A charging station 3 is connected to the charging cable 2 via a charging cable connection 30, which in the present case is formed via contacts 31, 32 that are only indicated and are in the form of connection terminals.

The charging cable 2 is designed for transmitting electrical energy from the charging station 3 to a traction battery for charging or discharging the traction battery, preferably for charging or discharging a traction battery of an electric vehicle 4 (see FIG. 1). The charging cable 2 contains a wiring harness 27, which contains a plurality of parallel lines (20, 22). At the vehicle side of the wiring harness 27, a connector 26 is formed to connect to the charging socket 40 of the electric vehicle 4 (see FIG. 1). In the connector 26, the lines are connected to contacts 28 provided for this purpose in the connector 26 according to the functionality thereof. Of the contacts 28, only a few are shown in FIG. 3 as examples. The connector 26 at the vehicle side shown in FIG. 3 on the right contains, among other things, a plurality of conductor contacts 21, which are connected to a corresponding number of charging current lines 20 of the charging cable 2 for energy transmission 20, the so-called power lines, which run along the charging harness 27. According to this embodiment, the charging cable 2 is optionally in the form of a three-phase alternating current charging cable 2 for 400 V and accordingly contains three phase conductors 20 or synonymously outer conductors (L1, L2, L3) as well as one conductor contact 21 per phase conductor 20, which are only schematically partially indicated here, as well as a conductor contact 21 for the neutral conductor (N) and a conductor contact 21 for the ground or respectively the protective earth contact (PE), wherein the latter two conductors (N, PE) are not shown for reasons of clarity.

Alternatively, the charging cable 2 can also be in the form of a two-phase alternating current charging cable or as a single-phase alternating current charging cable.

Furthermore, the charging cable 2 can also be in the form of a direct current charging cable. In this case, the charging current lines 20 correspond to the “DC+” and “DC−” conductors, through which the direct current is conducted through the cable.

The end of the charging cable 2 at the charging station side is, instead of containing a connector 26 at the vehicle side as shown in FIG. 2, designed so that at the charging station side the conductors 20, 22 of the charging cable 2 are connected directly to charging station 3, in this case with screw connections or clamp connections, wherein alternatively a connection is also possible with a separable or non-separable plug-in connector, for example.

This can prevent a customer from being able to remove the charging cable 2 himself. This may be to be prevented, for example, due to regulatory requirements. The charging cable 2 also has a plurality of sensors 24 in the connector 26 at the vehicle side, which are designed for measuring the temperature of the conductor contacts 21 of the charging current lines 20. If the measured temperature of the conductor contacts 21 exceeds a predetermined threshold value, the charging station may be designed to reduce the charging current or even interrupt the primary energy transmission via the charging current lines 20. Preferably, the reaction of the charging station is designed according to a specification, for example a specification of an authority or a standards document, for example according to E DIN EN 61851-23:2018-03 or VDE0122-2-3.

In addition, a plurality of temperature sensor units 5 is arranged in the wiring harness 27, wherein each temperature sensor unit 5 is assigned to one of the charging current lines 20, i.e., a phase conductor or outer conductor (L1, L2, L3), and determines the temperature of the respective assigned charging current line 20.

Accordingly, in the alternative version of the charging cable 2 as a direct current charging cable, a temperature sensor unit 5 for the “DC+” conductor and a temperature sensor unit 5 for the “DC−” conductor is to be provided.

Alternatively or additionally, a temperature sensor unit 5 can be formed at different points of the charging cable 2 for determining an average temperature of the charging current lines 20 at the respective point. Preferably, a temperature sensor unit 5 designed for determining the average temperature of the charging current lines 20 is respectively integrated at both ends of the charging cable 2, preferably—if present—in the connectors 26 of the charging cable 2.

The charging cable 2 also contains a signal line 22, which is configured and designed for digital communication, i.e., for the transmission of digital data. In the present case, the signal line 22 is in the form of a 1-Wire BUS. The digital signal line 22 contains a data wire 221 (DATA), via which digital data are transmitted, and also a ground wire 222 (GND). The 1-Wire BUS signal line 22 is designed in such a way that the power supply to connected units is carried out via the data wire 221. In other words, according to this preferred embodiment, the signal line 22 corresponds to a two-conductor 1-wire BUS with a parasitic power supply.

Instead of providing the ground wire 222, the protective earth conductor (PE) or the neutral conductor (N) of the primary energy transmission (not shown) can also be used as the ground wire, or respectively, the ground wire 222 can also be formed by the protective earth conductor (PE) or the neutral conductor (N) of the primary energy transmission.

Alternatively or additionally, the signal line may contain a power supply wire (not shown here). Furthermore, in addition or alternatively, a separate power supply can be provided by means of a corresponding power supply device (not shown here) in the charging station 3, which can, for example, provide a voltage of 3 V or 5 V, wherein the at least one conductor for the power supply (not shown here) is then arranged in the charging cable 2.

The sensors 24 and temperature sensor units 5 are communicatively connected to the 1-wire bus signal line 22. Accordingly, the temperature values provided by the temperature sensor units 5 and sensors 24 in digital form can be transmitted via the signal line 22 or read out from the sensors 24 and/or temperature sensor units 5 via the signal line 22.

The temperature sensor units 5 are accordingly in the form of digital temperature sensor units 5. In other words, each temperature sensor unit 5 provides the measured temperature value thereof as a digital signal or in the form of digital data.

The temperature sensor units 5 can contain an analog sensor, such as a thermocouple, a resistance thermometer, a negative temperature coefficient thermistor (NTC) and/or a positive temperature coefficient thermistor (PCT), with or without a downstream measuring transducer. The sensor is preferably coupled to an analogue-to-digital converter or a functionally equivalent alternative electronic element in order to convert the analog signal from the sensor into a digital signal.

Each temperature sensor unit 5 optionally contains an identifier, preferably a unique identifier, by means of which the respective temperature sensor unit 5 is preferably uniquely identifiable. The identifier can optionally be an address, but is not limited to the latter. By means of the identifier, the temperature value transmitted by the temperature sensor unit 5 can be identified at least as belonging to the charging current lines 20.

The temperature sensor units 5 preferably provide the measured or determined temperature values together with the identifier thereof to the signal line or respectively transmit a signal, or synonymously a data packet, which contains the identifier and the determined or measured temperature value.

Due to the formation of the charging cable 2 with the digital temperature sensor units 5 and the common digital signal line 22 (the 1-Wire-BUS), the temperature values of all charging current lines 20 can be transmitted via the one single signal line 22.

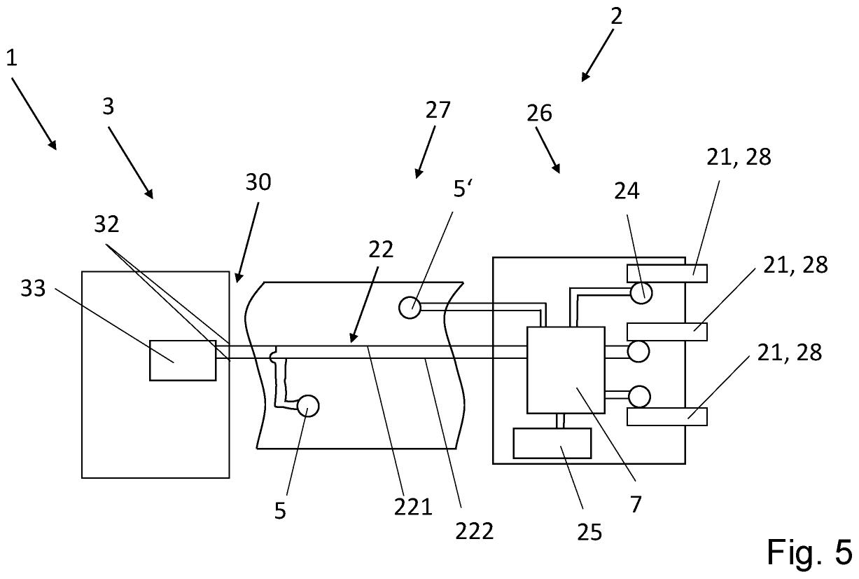

The charging cable 2 may also contain a memory module which is not shown here and which is designed and configured to store cable-specific data and is integrated in the charging cable 2, for example integrated in the connector 26 at the vehicle side, as shown in the optional version in FIG. 5. Alternatively or additionally, the memory module can also be integrated in the wiring harness 27, for example at the charging station side, preferably if the charging cable 2 does not contain a connector on the charging station side, and/or in the connector 26 at the charging station side.

The memory module can be communicatively connected to at least one of the conductors of the wiring harness 27, in this case preferably to the signal line 22 or to the wires 221, 222 thereof, in order to enable communication between the memory module and the charging station 3 via the connected conductor additionally for signal transmission or data transmission.

The cable-specific data may include at least one of a length of the charging cable 2 and/or a length of the wiring harness 27, a cable resistance, a specific cable resistance per given unit length, a specific conductor resistance of at least one of the charging current lines 20, and a cross-sectional area of at least one of the charging current lines 20. This information is preferably related to a reference temperature T_{REF}, which may be 20° C., for example.

In addition, the cable-specific data may include information about the type of cable, and the information may be at least one of information about the type of charging voltage, preferably alternating current or direct current, about a number of phases of the cable, a manufacturing site, a serial number, and a manufacturer.

Optionally, the memory module can be designed and configured to store the cable-specific data or at least part of it, in unencrypted or encrypted form and/or signed, and/or to make it available to be retrieved in an unencrypted or encrypted and/or signed form.

The signal line 22 can also be connected to at least one contact 28 in the connector 26 at the vehicle side, which can be used to provide data or signal transmission between the charging station 3 and the electric vehicle 4.

The charging station 3 contains charging conductor contacts 31 connected to a power grid (not shown) for the provision of the primary energy, i.e., the charging current, which are connected to the charging current lines 20 for the transmission of energy or the transmission of the charging current of the charging cable 2. In addition, the charging station 3 contains signal contacts 32, which are connected to the wires 221, 222 of the signal line 22 of the charging cable 2 for digital data transmission or signal transmission.

The charging station 3 also contains a computing device 33 for calculating losses occurring in the charging cable 2 connected to the charging cable connection 30 during energy transmission to the traction battery based on cable-specific data of the charging cable 2.

The computing device 33 is communicatively connected to the signal line 22 via the signal contacts 32 and can thus receive/read out at least the data/signals of the temperature sensor units 5.

The charging station 3 also contains an energy meter 6 communicating with the computing device 33, which is configured to measure the current delivered to the charging cable 2 at the charging contacts 31 and the voltage in the charging station 3.

The computing device 33 is designed to calculate the power dissipation in the charging cable 2 based on the cable resistance determined from the cable-specific data, the measured current values and/or voltage values, taking into account the temperature values provided by the temperature sensor units 5 for temperature compensation, and furthermore, to subtract the calculated losses of the charging cable 2 from the energy measured by the energy meter 6 for the correct calculation of the electrical energy output at the charging connector 26. For example, the temperature compensation can be carried out using the formula (2) mentioned above.

Alternatively, the energy meter 6 or the functionality thereof can be integrated in the computing device 33.

Preferably, exactly one signal line 22 is provided in the wiring harness 27 and thus in the charging cable 2, which as the central signal line 22 substantially provides the entire communication or signal transmission of the charging cable 2.

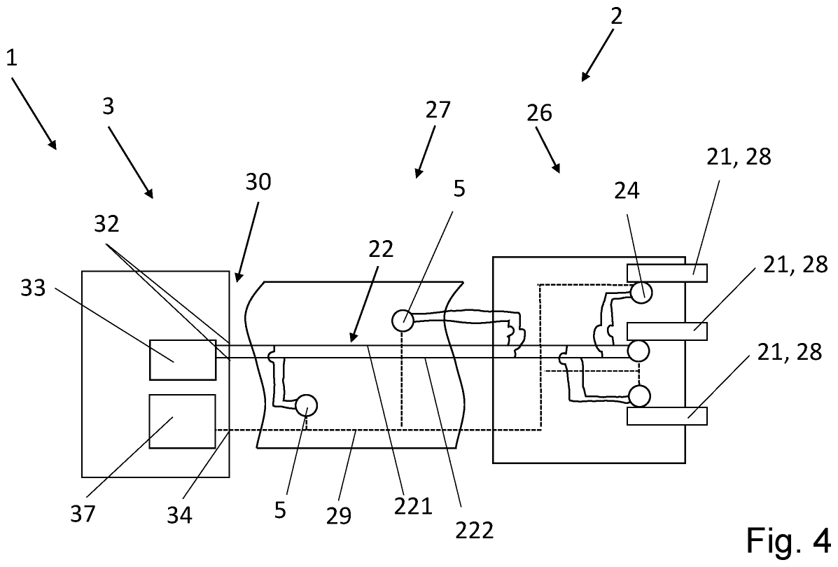

FIG. 4 shows schematically a cross-sectional view through a charging system 1 for charging or discharging a traction battery of an electric vehicle 4 according to another embodiment. The charging system 1 corresponds substantially to that shown in FIG. 3, wherein instead of the parasitic power supply of the components communicatively connected to the signal line 22, i.e., at least the temperature sensor units 5 and the sensors 24, via the data wire 221 of the signal line 22, the aforementioned components are supplied separately via a separate secondary power line 29. For this purpose, the separate secondary power line 29 is connected to a secondary power supply 37 arranged in the charging station 3 via a secondary current contact 34. For the sake of a better overview, the charging current lines 20 for the transmission of the primary energy are not shown in FIG. 4.

FIG. 5 shows schematically a cross-sectional view through a charging system 1 for charging or discharging a traction battery of an electric vehicle 4 according to another embodiment. The charging system 1 corresponds substantially to that shown in FIG. 3, wherein the differences from the version according to FIG. 3 are set out below. For the sake of a better overview, the charging current lines 20 for the transmission of the primary energy are not shown in FIG. 4.

According to this embodiment, the signal line 22 is connected to a digital computing unit 7 of the charging cable 2, which preferably contains a so-called controller, especially preferably a microcontroller (μC), or respectively, is formed by it. The computing unit 7 is optionally arranged in the connector 26 at the vehicle side here. However, it can also be arranged in whole or in part in the wiring harness 27 or in whole or in part in a connector at the charging station side.

The digital computing unit 7 is connected to the sensors 24 and communicates the data from the sensors 24 via the signal line 22 to the computing device 33 of the charging station 3. The sensors 24 can be in the form of analogue or digital sensors 24, in the former case the computing unit 7 is designed to convert the analog signals of the analog sensors 24 into digital signals before the computing unit 7 transmits them via the signal line 22.

As can also be seen from FIG. 5, a temperature sensor unit 5 is directly connected to the signal line 22 for measuring the temperature of one of the charging current lines 20. Another temperature sensor unit 5′ is communicatively connected to the computing unit 7. Accordingly, the computing device 33 of the charging station 3 communicates with this temperature sensor unit 5 via the computing unit 7 of the charging cable 2.

Optionally, a memory module 25 is provided, which in the present case is optionally connected to the computing unit 7. Alternatively or additionally, the memory module 25 can also be directly communicatively coupled to the signal line 23.

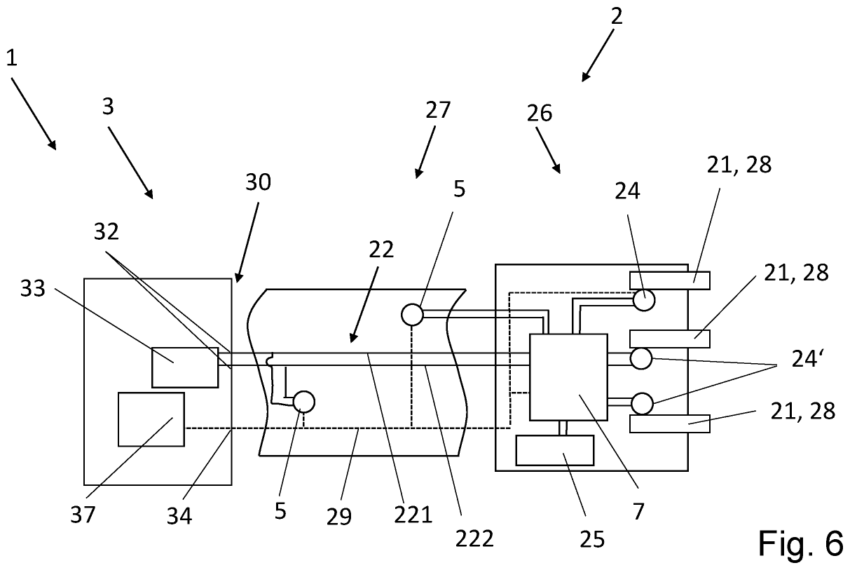

FIG. 6 shows a schematic cross-sectional view through a charging system 1 for charging or discharging a traction battery of an electric vehicle 4 according to another embodiment. The charging system 1 corresponds essentially to that shown in FIG. 5, wherein instead of the parasitic power supply of the components communicatively connected to the signal line 22, i.e., at least the temperature sensor units 5 and the computing unit 7 as well as the sensors 24, via the data wire 221 of the signal line 22, the aforementioned components are supplied at least partially separately via a separate secondary power conductor 29 analogous to FIG. 4. For this purpose, the separate secondary power conductor 29 is connected via a secondary current contact 34 to a secondary power supply 37 arranged in the charging station 3. For the sake of clarity, the charging current lines 20 for the transmission of the primary energy are not shown in FIG. 6.

The power supply of the components of the charging cable 2 connected to the computing unit 7 can alternatively be provided through the secondary power conductor 29, as indicated by sensor 24 as an example, or by the computing unit 7, as indicated by the sensors 24′ as an example.

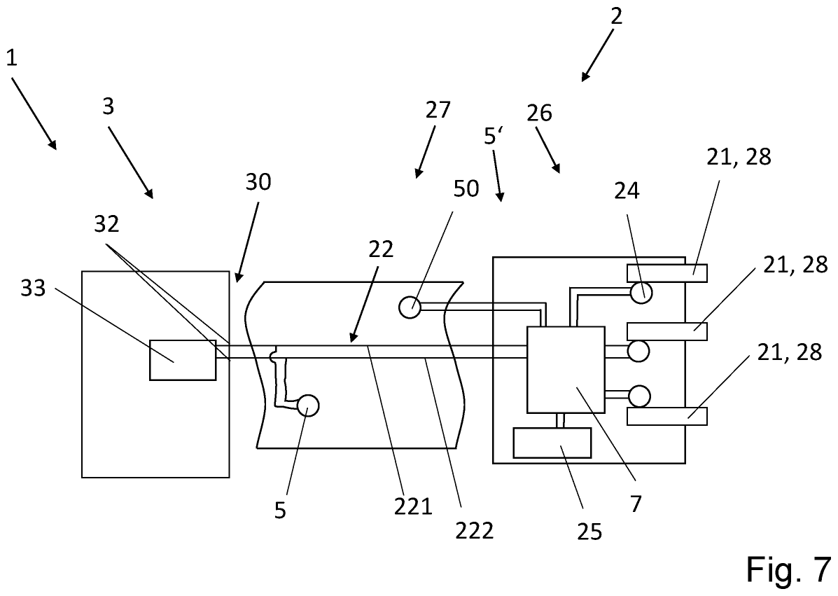

FIG. 7 shows schematically a cross-sectional view through a charging system 1 for charging or discharging a traction battery of an electric vehicle 4 according to another embodiment. The charging system 1 corresponds essentially to that shown in FIG. 5, wherein an analogue temperature sensor which is marked with the reference sign 50 is designed and configured for measuring the temperature of one of the charging current lines 20, in this case optionally the phase conductor L1 (not shown). The analog temperature sensor 50 is connected to the computing unit 7, which converts the analog signals of the analog temperature sensor 50 into digital signals and provides them via the signal line 22. Accordingly, the analogue temperature sensor 50 and the computing unit 7 form a digital temperature sensor unit 5′, which communicates measured temperature values in the form of digital signals to or via the signal line 22.

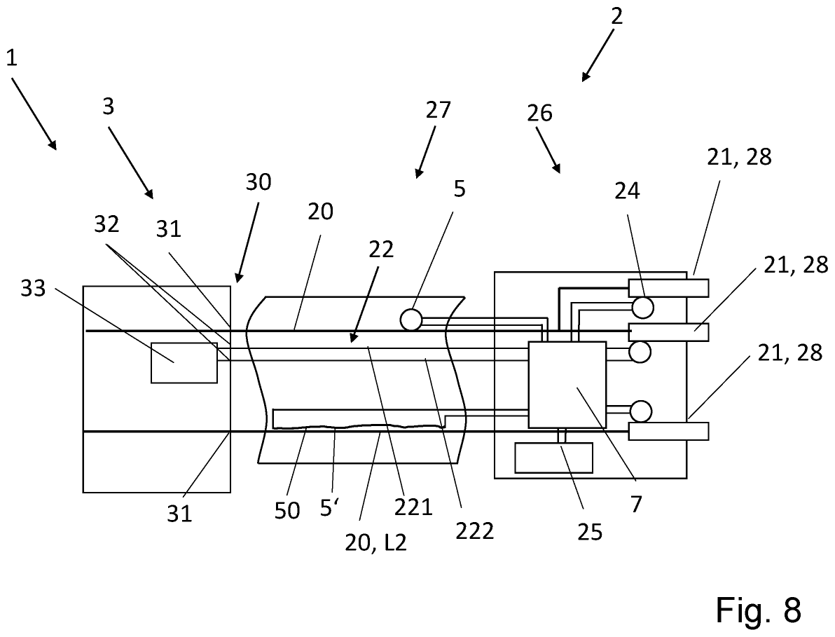

FIG. 8 shows a schematic cross-sectional view through a charging system 1 for charging or discharging a traction battery of an electric vehicle 4 according to another embodiment. The charging system 1 corresponds essentially to that from FIG. 5, wherein here a temperature sensor unit 5′ comprises an elongated temperature sensor 50, which extends over a predetermined area of the wiring harness 27 along a charging current line 22 and is designed and configured for measuring the temperature of one of the charging current lines 20, in the present case optionally the phase conductor L2.

To the extent applicable, all the individual features shown in the exemplary embodiments may be combined with each other and/or exchanged without departing from the scope of the invention.

### REFERENCE SIGN LIST

1 System
2 Charging cable
20 Charging line for energy transmission/charging current line
21 Charging conductor contact/conductor contact
22 Signal line for signal transmission
221 Data wire (DATA)
222 Ground (GND)
23 Signal contact
24 Sensor
Memory module
26 Connector
27 Wiring harness
28 Contact
29 Secondary power conductor
3 Charging station
30 Charging cable connection
31 Power conductor contact
32 Signal contact
33 Computing device
34 Secondary power contact
37 Secondary power supply
4 Electric vehicle
40 Charging socket
5 Temperature sensor unit
50 Temperature sensor
6 Energy meter
7 Computing unit

1: A charging cable configured to transmit a charging current from a charging station to a traction battery for at least one of: charging and discharging the traction battery, containing a plurality of charging current lines designed and configured for transmitting the charging current from the charging station to the traction battery, comprising:
a temperature sensor unit configured to be assigned to each charging current line, which is configured to determine the temperature of the assigned charging current line, wherein the temperature sensor units are connected to a signal line configured to provide the temperature values determined by the temperature sensor units to the charging station.

2: The charging cable as claimed in claim 1, wherein at least one of: exactly one signal line is provided in the charging cable, the signal line is configured and designed for the transmission of digital signals, and the temperature sensor units are digital temperature sensor units.

3: The charging cable as claimed in claim 2, wherein the temperature sensor units are configured and designed so that the digital signals thereof contain an identifier that uniquely identifies the temperature sensor unit, and the temperature value of the charging current line assigned to the temperature sensor unit.

4: The charging cable as claimed in claim 3, wherein the signal line is a data bus conductor.

5: The charging cable as claimed in claim 4, wherein the temperature sensor units are assigned to the charging current lines in such a way that one temperature sensor unit is assigned exactly to one charging current line, wherein at least one of: the respective temperature sensor unit only determines the temperature of the charging current line assigned to it, and in such a way that temperature sensor units are arranged spaced apart from each other at different points of the charging cable and each of the spaced apart temperature sensor units determines an average temperature of the charging current lines at the respective point.

6: The charging cable as claimed in claim 5, wherein a memory module designed and configured for storing cable-specific data is provided in the charging cable, which is communicatively connected to the signal line, wherein the cable-specific data contain at least one of a length of the charging cable and a length of the wiring harness, a cable resistance in relation to a reference temperature, a specific cable resistance per given unit length in relation to a reference temperature, a specific conductor resistance of at least one of the charging current lines in relation to a reference temperature, a cross-sectional area of at least one of the charging current lines, and information about the type of cable, wherein the information includes at least one of information about the type of charging voltage, alternating current or direct current, about a number of phases of the cable, a manufacturing site, a serial number, and a manufacturer.

7: The charging cable as claimed in claim 6, wherein a computing unit is arranged in the charging cable, at least partially in a connector at the vehicle side of the charging cable, wherein at least one of: the computing unit is connected to the signal line, the computing unit is connected to at least one temperature sensor unit, and the computing unit forms a temperature sensor unit together with a temperature sensor.

8: A charging station configured to transmit a charging current to a traction battery for at least one of: charging and discharging the traction battery containing at least one charging cable connection for connecting a charging cable, the charging cable connection having at least one conductor contact for contacting a charging current line of the charging cable configured for charging current transmission, and at least one signal contact for contacting a signal line of the charging cable configured and designed for signal transmission, and also containing a computing device connected to the at least one signal contact for calculating losses occurring in the charging cable connected to the charging cable connection during the charging current transmission to the traction battery based on cable-specific data, wherein
the computing device is designed and configured for calculating the losses in the charging cable by taking into account temperature values of the charging current lines of the charging cable provided via the signal line of the charging cable.

9: The charging station as claimed in claim 8, wherein the computing device is configured and designed to receive the temperature values from the signal line in the form of digital signals, wherein the digital signals contain at least one identifier uniquely identifying a temperature sensor unit of the charging cable, and at least one of: a temperature value of a charging current line assigned to the temperature sensor unit and an average temperature value of the charging lines at a specified point in the charging cable.

10: A charging system for transmitting electrical energy from a charging station to a traction battery for charging or discharging the traction battery by means of a charging cable connected to the charging station and the traction battery, comprising: characterized by
at least one of: a charging cable and a charging station;
wherein the charging cable comprises a temperature sensor unit configured to be assigned to each charging current line, which is configured to determine the temperature of the assigned charging current line, wherein the temperature sensor units are connected to a signal line configured to provide the temperature values determined by the temperature sensor units to the charging station; and
wherein the charging station is configured to transmit a charging current to the traction battery for at least one of: charging and discharging the traction battery containing at least one charging cable connection for connecting a charging cable, the charging cable connection having at least one conductor contact for contacting a charging current line of the charging cable configured for charging current transmission, and at least one signal contact for contacting a signal line of the charging cable configured and designed for signal transmission, and also containing a computing device connected to the at least one signal contact for calculating losses occurring in the charging cable connected to the charging cable connection during the charging current transmission to the traction battery based on cable-specific data, wherein the computing device is designed and configured for calculating the losses in the charging cable by taking into account temperature values of the charging current lines of the charging cable provided via the signal line of the charging cable.

11: A method for transmitting a charging current from a charging station to a traction battery for at least one of: charging and discharging the traction battery including the steps of
providing electrical energy via the charging station,
conducting the electrical energy from the charging station to the traction battery via a charging cable connected to the charging station and the traction battery, and calculating losses occurring in the charging cable during the energy transmission to the traction battery based on cable-specific data,
wherein the temperature of each charging current line of the charging cable configured and designed for transmitting the charging current from the charging station to the traction battery is determined by respective temperature sensor units that each are assigned to a respective charging current line,
wherein the determined temperature values are transmitted to the charging station via a signal line connected to the temperature sensor units, and
wherein the calculation of the losses occurring in the charging cable during the transmission of energy to the traction battery is carried out by taking into account the temperature values of each of the charging current lines determined and transmitted in the charging cable.

12: The charging cable as claimed in claim 4, wherein the signal line is at least one of: a standard bus, a proprietary bus, and a 1-wire bus.

13: The charging cable as claimed in claim 5, wherein the temperature sensor units are assigned to the charging current lines in such a way that each temperature sensor unit is assigned exactly to one charging current line.

14: The charging cable as claimed in claim 7, wherein the temperature sensor is an analogue temperature sensor.
